(19) United States
(12) Patent Application Publication
(10) Pub. No.: US 2004/0240297 A1
(43) Pub. Date: Dec. 2, 2004

(54) Data protecting apparatus and method, and computer system

(76) Inventors: Kenichi Shimooka, Yokohama (JP); Masayasu Asano, Yokohama (JP)

Correspondence Address: MATTINGLY, STANGER & MALUR, P.C., 1800 DIAGONAL ROAD, SUITE 370, ALEXANDRIA, VA, 22314, US

(21) Appl. No.: 10/803,945

(22) Filed: Mar. 19, 2004

(30) Foreign Application Priority Data
May 30, 2003 (JP) 2003-154870

(51) Int. Cl. G11C 7/00

(52) U.S. Cl. 365/222

(57) ABSTRACT

When an computer fraud against a computer system is detected, data of the computer system is protected.

A data protection apparatus protects data in a storage volume in a computer system comprising the storage volume assigned for storing data, a computer for reading and writing data from and to the storage volume, and a storage control unit for controlling communication between the computer and the storage volume. The data protection apparatus comprises an event detection unit for detecting an event occurrence, and a path disconnection unit for instructing the storage control unit to stop communication between the computer and the storage volume.

### BACKGROUND OF THE INVENTION

The present invention relates to a technique of protecting data in a computer system at the time of detecting an computer fraud against the computer system.

Recently, as computer networks become popular, service businesses using computer systems, such as electric commerce, are flourishing. On the other hand, damage such as data destruction, data leakage, data alteration and the like owing to illegal intrusion into a computer system, a computer virus, or the like (hereinafter, these are generically referred to as computer fraud(s)) becomes serious problems. There is the possibility that transaction information held on a computer system is lost by data destruction or the like owing to these computer frauds, causing tremendous losses. As a result of this, confidence in a company that operates the computer system may be lost. Further, generally speaking, large costs and much time are required to recover damaged data. Thus, it is very important to protect data against computer frauds.

As countermeasures against computer frauds, prevention should be mentioned first. Conventionally, computer frauds on a computer system have been prevented by installation of a firewall between the computer system and an external network, user authentication using a one-time password, setting of ACL (Access Control List) defining files/programs accessible by each user, and the like. However, techniques of computer frauds are developed and diversified day by day, and thus, as a matter of fact, it is impossible to prevent computer frauds perfectly.

Accordingly, by way of precaution against unprevented intrusion, monitoring and an ex post facto countermeasure become important. As conventionally-known typical monitoring means, may be mentioned IDS (Intrusion Detection System) for coping with illegal intrusion, virus detection software for coping with computer viruses.

IDS monitors illegal intrusion and the like by monitoring a log file and analyzing port scan, for example. When an illegal intrusion or the like is detected, a session with an intruder is disconnected, or a front-end switches existing between an intruded computer system and an external network is operated to disconnect the path from the intruder. Further, virus detection software detects computer viruses by performing pattern matching between file contents and code patterns of computer viruses, for example. When a computer virus is detected, an infected file is deleted, or a virus pattern is erased. Details of these techniques are described, for example, in Foundation for Multimedia Communications, Network Management Section, “Introduction to Network Management for Beginners”, 6.3.3. Intrusion Detection System, [online], May 15, 2002 (found on Dec. 19, 2002) on the Internet <URL:http//www.fmmc.or.jp/~fm/nwmg/manage/main.html>.

### SUMMARY OF THE INVENTION

Generally speaking, IDS requires a certain period of time for detecting an illegal intrusion from its occurrence. Sometimes, an intruder uses this time to put a Trojan horse or to open a backdoor for the next intrusion. Here, the Trojan horse means a disguised program that gives rise to a destructive action or causes infection with a computer virus once the program is executed being taken as a harmless program.

In these cases, it is not possible to sufficiently protect data in a computer system by the above-mentioned disconnection of a session or disconnection of a path at the front end. This is because there is a possibility that an authorized user activates the Trojan horse without knowing it, or the intruder intrudes again by entering through the backdoor to pass through the IDS.

Further, in the case of infection with a self-propagating computer virus that infects other files or programs one after another, even when a virus detection software detects and deletes the computer virus, the infection may spread before other files or the like are inspected.

Thus, an object of the present invention is to protect data in a computer system when an computer fraud against the computer system is detected.

To attain the object, a first mode of the present invention provides a data protection apparatus for protecting data in a storage volume in a computer system comprising said storage volume assigned for storing data, a computer for reading and writing data from and to said storage volume, and a storage control unit for controlling communication between said computer and said storage volume, wherein said data protection apparatus comprises an event detection unit for detecting occurrence of an event, and a path disconnection unit for instructing said storage control unit to stop communication between said computer and said storage volume, when said event detection unit detects an event.

As an event whose occurrence is to be detected, can be mentioned an computer fraud detected by an intrusion detection unit or a virus detection unit.

According to the present mode, when an computer fraud is detected, it is possible to protect data by disconnecting a back-end path between the computer suffering from the computer fraud and its storage volume.

Further to attain the above object, a second mode of the present invention provides a data protection apparatus for protecting data in a storage volume in a computer system, with said computer system comprising said storage volume assigned for storing data, a replicated volume assigned for storing data duplicated from said storage volume, and a storage control unit for controlling data transfer from said storage volume to said replicated volume, wherein said data protection apparatus comprises: an event detection unit for detecting occurrence of an event; and a replication stopping unit for instructing said storage control unit to stop data transfer from said storage volume to said replicated volume, when said event detection unit detects an event.

The storage control unit may transfer write data of the storage volume to said replicated volume with a delay of a given time. Or, a plurality of replicated volumes may be provided so that the storage control unit may switch a transfer destination of write data of the storage volume, at given time intervals among the plurality of replicated volumes.

According to the present mode, it is possible to secure data replication before occurrence of an computer fraud.

The above and other features of the present invention will be clear from the description and the attached drawings.

### BRIEF DESCRIPTION OF THE DRAWINGS

FIG. 1 is a block diagram showing a system configuration of a first embodiment of the present invention;

FIG. 2 is a sequence diagram showing a process flow from an occurrence of an computer fraud against a host 40 to a protection of data in a storage volume 64 in the first embodiment;

FIG. 3 is a diagram showing an example of a zoning table 100 held by a switch 50 in the first embodiment;

FIG. 4 is a diagram showing an example of a path configuration table 110 held by a controller 63 in the first embodiment;

FIG. 5 is a diagram showing an example of an ACL table 120 held by the controller 63 in the first embodiment;

FIG. 6 is a block diagram showing a system configuration of a second embodiment of the present invention;

FIG. 7 is a block diagram showing a system configuration of a third embodiment of the present invention;

FIG. 8 is a sequence diagram showing a processing flow for switching replicated volumes 67a-67c as destinations of replication of a storage volume 64 in the third embodiment; and

FIG. 9 is a diagram showing an cascade example of replicated volumes in the third embodiment.

### DESCRIPTION OF THE PREFERRED EMBODIMENTS

[First Embodiment]

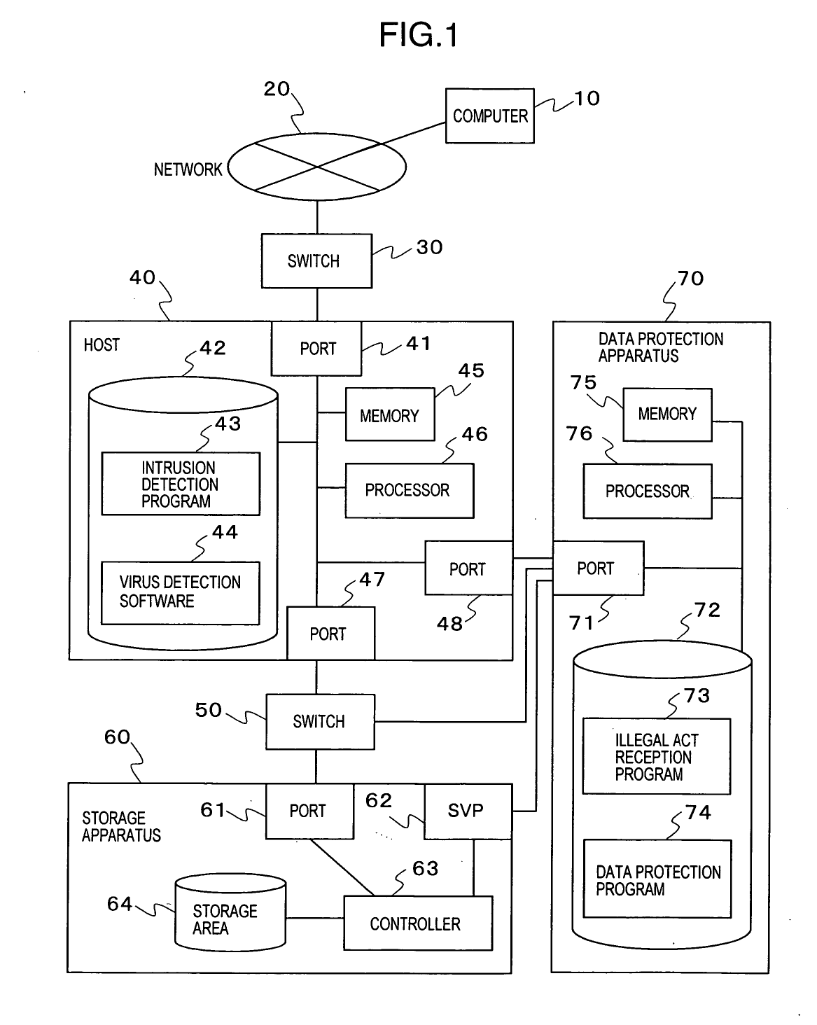

FIG. 1 is a block diagram showing a system configuration of a first embodiment of the present invention.

A system of the first embodiment comprises a front-end switch 30, a host 40, a back-end switch 50, a storage 60, and a data protection apparatus 70, and is connected to a network 20.

Although the data protection apparatus 70 is described in the present and other embodiments as one independent apparatus, the data protection apparatus 70 may be provided inside the host 40 or built in the switch 30. Further, although the switch 50 also is described as one independent apparatus in the present and other embodiments, the switch 50 may be provided inside the host 40 or the storage 60. Further, although the storage 60 also is described as one and independent apparatus in the present and other embodiments, the storage 60 may be provided in the host 40. Further, although the relation between the host 40 and the data protection apparatus 70 is illustrated as a one-to-one relation in FIG. 1 and other figures, the relation may be a many-to-one relation. Further, although the relation between the host 40 and the storage 60 is illustrated also as a one-to-one relation in FIG. 1, the relation may be one-to-many, many-to-one, or many-to-many.

A computer 10 connected to the network 20 is used as a terminal for using the service provided by the host 40. However, a cracker may use the computer 10 to perform an computer fraud against the host 40. As the computer 10, a PC (Personal Computer) or a portable information terminal may be mentioned, for example. Although only one computer 10 is illustrated in FIG. 1 and other figures, a plurality of the computers 10 may exist.

The network 20 may be Internet using IP (Internet Protocol), LAN (Local Area Network), WAN (Wide Area Network), or SAN (Storage volume Network) using FC (Fiber Channel), for example.

The front-end switch 30 controls a connection between the network 20 and the host 40. However, in the present and other embodiments, it is possible that the switch 30 does not exist and the network 20 and the host 40 are connected directly.

The host 40 provides services such as electric commerce and video streaming to the computer 10 through the network 20. However, the host 40 is not limited to a host that provides services, and may be a host that manages internal data without providing services to the outside. The host 40 comprises: a port 41 functioning as an interface with the front-end switch 30; a storage volume 42 storing an intrusion detection program 43 for detecting an illegal access and a virus detection software 44 for detecting computer viruses; a memory 45; a processor 46; a port 47 functioning as an interface with the back-end switch 50; and a port 48 functioning as an interface with the data protection apparatus 70.

It is described in the present and other embodiments that the intrusion detection program 43, the virus detection software 44, and the like are stored in the storage volume 42 provided in the host 40. However, the intrusion detection program 43, the virus detection software 44 and the like may be stored in the storage 60, the data protection apparatus 70, a storage volume of another computer, or a storage medium. In these cases, the host 40 can dispense with the storage volume 42. Further, it is favorable that both the intrusion detection program 43 and the virus detection software 44 exist. However, either the intrusion detection program 43 or the virus detection software 44 may not exist. Further, although FIG. 1 and other figures illustrates one port 41 and one port 47, a plurality of ports 41 and a plurality of ports 47 may exist.

The storage 60 is a storage provided with a storage volume 64 for storing data to be protected. The storage volume 64 stores, for example, programs for providing services to the computer 10, and other data. Further, the storage 60 comprises: a port 61 which is an interface with the switch 50 for sending and receiving data; an SVP (Service Processor) 62 which is an interface for acquiring and setting configuration information; and a controller 63 for controlling the connection between the port 61 and the storage volume 64 based on the configuration information set by the SVP 62. Although FIG. 1 illustrates one port 61 and one storage volume 64, a plurality of ports 61 and a plurality of storage volumes 64 may exist.

The data protection apparatus 70 is an apparatus characteristic of the present invention, and comprises: a port 71 functioning as an interface with the host 40; a storage volume 72; a memory 75; and a processor 76. The storage volume 72 stores an computer fraud receiving program 73 for receiving computer fraud detection results of a below-mentioned intrusion detection unit 43x and a virus detection unit 44x and a data protection program 74 for performing processes of disconnecting a path between the host 40 and the storage volume 64 used by the host 40. The computer fraud receiving program 73 and the data protection program 74 may be stored in another computer, a storage or a storage medium. In that case, the storage volume 72 can be omitted. The data protection apparatus 70 can be composed as a dedicated apparatus, or composed, for example, by a general information processing apparatus such as a PC.

Next, will be described operation in the system of the present embodiment.

The host 40 loads a program for providing service onto the memory 45, and the processor 46 executes the program. The above-mentioned program reads or writes data from or to the storage volume 64 through the port 47, the back-end switch 50, and the port 61 and controller 63 of the storage 60, in response to a request from the computer 10, or at regular intervals, or on a occasion of occurrence of a certain event, and provides the service to the computer 10 through the port 41, the front-end switch 30 and the network 20.

At the same time, the intrusion detection program 43 and the virus detection software 44 are loaded onto the memory 45 and executed by the processor 46. As a result, the intrusion detection unit 43x (not shown) and the virus detection unit 44x (not shown) are virtually realized in the host 40, and these units 43x and 44x monitor whether the host 40 suffers from an computer fraud or the like. Here, the intrusion detection program 43 and the virus detection software 44 may be loaded onto the memory of the data protection apparatus 70 or a memory on another computer, to monitor the host 40 through a network.

Further, the computer fraud receiving program 73 in the data protection apparatus 70 is loaded onto the memory 75 and executed by the processor 76. As a result, an computer fraud receiving unit 73x (not shown) is virtually realized in the data protection apparatus 70, to await a notice of detection of an computer fraud. Here, the computer fraud receiving unit 73x may actively monitor whether the intrusion detection unit 43x or the virus detection unit 44x has detected an computer fraud. In that case, for security of the data protection apparatus 70 itself, it is favorable to assure that access from the data protection apparatus 70 to another apparatus is permitted while access from another apparatus such as the host 40 to the data protection apparatus 70 is not permitted.

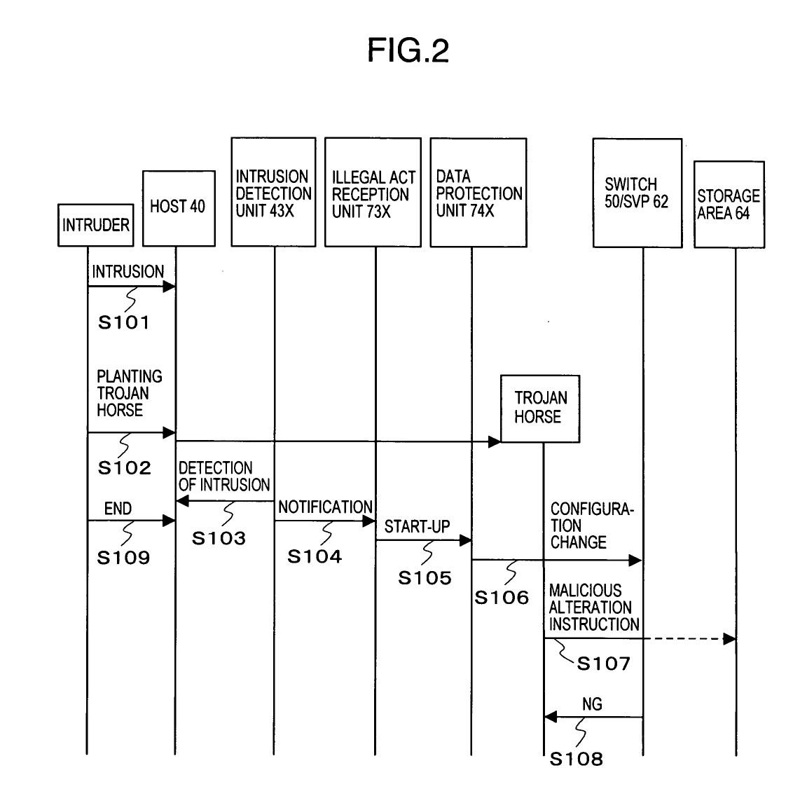

FIG. 2 is a sequence diagram showing a flow from occurrence of an computer fraud against the host 40 to data protection process in the storage volume 64.

A cracker (intruder) uses the computer 10 to illegally intrude into the host 40 or to send a computer virus to the host 40 (S101).

When the intrusion detection unit 43x detects an illegal intrusion into the host 40 (S103), then the intrusion detection unit 43x notifies the computer fraud receiving unit 73x of the illegal intrusion, through the ports 48 and 71 (S104). Further, similarly when the virus detection unit 44x detects a computer virus, then the virus detection unit 44x notifies the computer fraud receiving unit 43x of the computer virus detection, through the ports 48 and 71.

Receiving the detection of the computer fraud against the host 40, the computer fraud receiving unit 73x loads the data protection program 74 onto the memory 75, and makes the processor 76 execute the program 74 (S105). As a result, a data protection unit 74x (not shown) is virtually realized in the data protection apparatus 70. Here, the data protection program 74 may be loaded onto the memory 75 in advance.

The data protection unit 74x instructs the switch 50 or the SVP 62 through the port 71 to change the configuration so as to disconnect a back-end path between the host 40 and the storage volume 64 (S106).

Consequently, even when a Trojan horse is planted in the storage volume 64 or the like before the intrusion detection unit 43x detects the illegal intrusion, the back-end path between the host 40 and the storage volume 64 is disconnected. Thus, even when the Trojan horse tries to alter data in the storage volume 64 (S107), the host 40 can not access the storage volume 64 and the alteration ends in a failure (S 108).

Thus, according to the present embodiment, it is possible to prevent data destruction that may be resulted from an illegal intrusion or its planted fraud.

Further, even when an intruder opens a backdoor for the next intrusion before the intrusion detection unit 43x detects an illegal intrusion, the back-end path between the host 40 and the storage volume 64 is disconnected at the time of next intrusion, and thus, the data in the storage volume 64 can not be accessed either.

In the case where a self-propagating computer virus is planted in the storage volume 64, there is a possibility that another file has been infected at a point of time when the virus detection unit 44x detects the computer virus. However, the data protection program 74 disconnects the path between the host 40 and the storage volume 64, and accordingly, the infected file can not be loaded onto the memory 45 and executed (i.e., can not activate). In other words, it is possible to protect the data in the storage volume 64 from further infection (destruction).

Next, will be described a method of disconnecting the back-end path in S106. Although the present invention is not limited with respect to a method of disconnecting the back-end path, it is possible to mention a method of using zoning of the switch 50, a method of using path configuration management for the storage 60, and a method of using ACL of the storage 60, for example. The data protection unit 74x may perform one of these methods, or perform a combination of these methods.

First, will be described the method of using zoning of the switch 50. Zoning is a function that a switch permits communication between specific ports only. For example, when a zone consists of ports a, b and c, this switch controls communication so that the port b can communicate with the ports a and c but can not communicate with a port d.

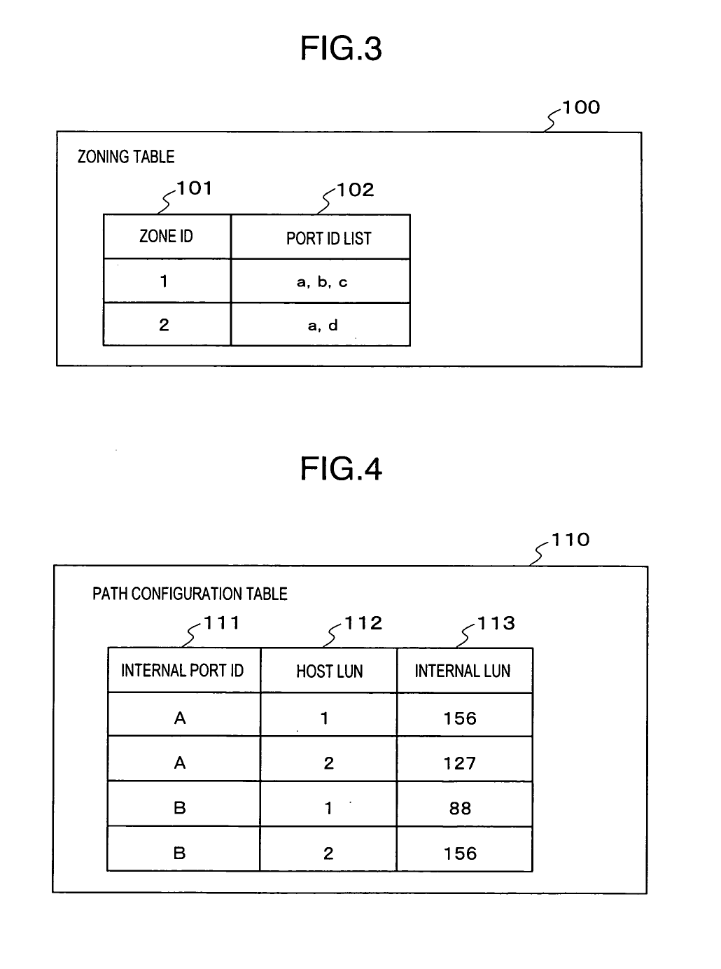

FIG. 3 is a diagram showing an example of a zoning table 100 held by the switch 50 in the present embodiment.

A zone ID 101 is a value for identifying a zone uniquely in the switch 50. Although FIG. 3 expresses a zone ID 101 as a number, it is possible to use a character string.

A port ID list 102 is a list of port IDs of ports constituting a zone. A port ID is a value for identifying a port uniquely. As a port ID, a port name or a WWN (World Wide Name) may be used, for example.

The data protection unit 74x instructs the switch 50 through the port 71 to delete the port 47 from all the port ID list 102 of the zoning table 100. Here, when a port ID list 102 has only one port, the whole zone may be deleted.

For example, when the port 47 is the port a, in the example of FIG. 3, the data protection unit 74x makes the zone ID 1 consist of ports b and c only.

As a result, the port 47 can not access any storage 60, and accordingly, the data in the storage volume 64 can be protected.

Next, will be described the method of using path configuration management for the storage 60, as the method of disconnecting the back-end path.

Path configuration management is a function of managing correspondence between storage volume IDs seen from the host and storage volume IDs inside a storage. The host can not access a storage volume that is not set with such correspondence.

FIG. 4 is a diagram showing an example of a path configuration table 110 held by the controller 63 in the present embodiment.

An internal port ID 111 is an ID for identifying a port 61 uniquely inside the storage 60. A host LUN (Logical Unit Number) 112 is an ID of a storage volume 64 seen from the host 40. An internal LUN 113 is an ID for identifying a storage volume 64 uniquely inside the storage 60.

In the example of FIG. 4, when the host 40 tries to access the first storage through the port A, the host 40 accesses the storage volume 64 whose internal LUN is 156.

Although a host LUN 112 and an internal LUN 113 are expressed by numbers in FIG. 4, each may be expressed by a character string.

The data protection unit 74x instructs the controller 63 through the port 71 and the SVP 62 to delete any item corresponding to the storage volume 64 used by the host 40 from the path configuration table 110. To know any item corresponding to the storage volume 64, the intrusion detection unit 43x or the virus detection unit 44x sends information on the internal port ID 111 of the port 61 and the host LUN 112 of the storage volume 64 used by the host 40, at the same time when the intrusion detection unit 43x or the virus detection unit 44x notifies the computer fraud receiving unit 73x of detection of an computer fraud. The data protection unit 74x receives the above-mentioned information from the computer fraud receiving unit 73x, and requests the controller 63 to delete the items corresponding to the above-mentioned information from the path configuration table 110. In the case where the storage volume 64 used by the host 40 does not change at the time of operation, a system administrator of the present embodiment may give information on the host 40 and the internal LUN 113 of the storage volume 64 to the data protection unit 74x in advance. An input device such as a keyboard or a mouse of the data protection apparatus 70 is used to set the information through a UI (User Interface) provided by the data protection unit 74x. In this case, when the computer fraud receiving unit 73x detects an computer fraud against the host 40, the data protection unit 74x uses the information to request the controller 63 to delete all the items corresponding to the internal LUN 113 of the storage volume 64 from the path configuration table 110.

For example, when the internal LUN 113 of the storage volume 64 used by the host 40 is 156, the data protection unit 74x deletes items in the first and fourth lines in the example of FIG. 4.

As a result, the storage volume 64 can not be accessed from any host 40. Thus, the data in the storage volume 64 is protected.

Next, will be described the method of using ACL as the method of disconnecting the back-end path.

ACL of a storage means a function that, for each storage volume, only access from specific hosts is permitted.

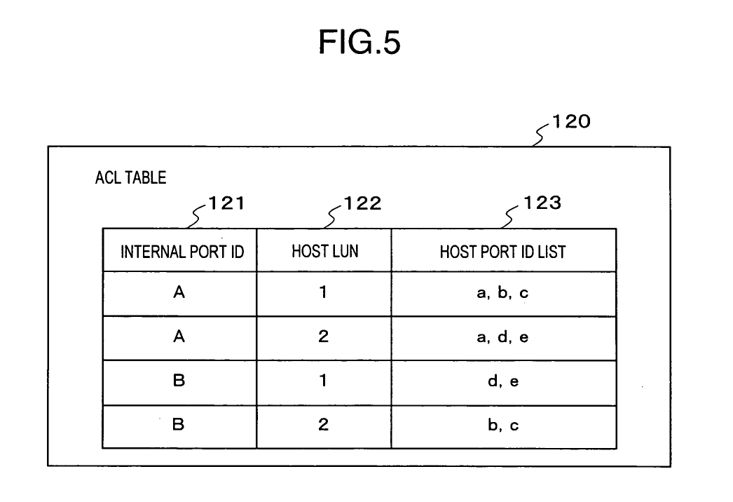

FIG. 5 is a diagram showing an example of an ACL table 120 held by the controller 63 in the present embodiment.

An internal port ID 121 is an ID for identifying a port 61 uniquely in the storage 60. A host LUN 122 is an ID of a storage volume seen from the host 40. Here, instead of a host LUN, may be used an internal LUN, which is an ID for identifying a storage volume 64 uniquely in the storage 60. A host port ID list 123 is a list of port IDs of ports 47 that can use a path expressed by a port ID 121 and a host LUN 122. Namely, in the case of FIGS. 4 and 5, the ports a, b and c on the side of the host can access the storage volume 64 whose internal LUN is 15 through the port A on the side of the storage, while the ports d and e can not.

The data protection unit 74x instructs the controller 63 through the port 71 and the SVP 62 to delete the port 47 from all the host port ID list 123 in the ACL table 120. Here, in the case where a host port ID list 123 includes no port, that item itself can be deleted.

For example, assuming that the port 47 is the port a, the data protection unit 74x deletes the port a from the first and second lines in the example of FIG. 5.

As a result, the port 47 can not access any storage volume 64. Thus, the data in the storage volume 64 can be protected.

“The method of using zoning of the switch 50” and “the method of using ACL of the storage 60” have the equal effect, while “the method of using path configuration management for the storage 60” has slightly different effects. In the former two methods, only the host 40 suffering from an computer fraud becomes unable to access the storage volume 64, while in the latter method, all hosts become unable to access the storage volume 64. Namely, when one of the former methods is employed, a host that does not suffer from an computer fraud can access the storage volume 64 without interruption, and can continue to provide service. Thus, it is favorable that the data protection unit 74x employs one of the former methods in the case where a plurality of hosts share the storage volume 64 and obviously the data of the storage volume 64 has not been altered and intruded by a computer virus, and employs the latter method in the other cases.

As described above, in the present embodiment, when the intrusion detection unit 43x or the virus detection unit 44x detects an computer fraud, the data protection unit 74x disconnects the back-end path between the host 40 and the storage volume 64. As a result, even if a Trojan horse is planted or a backdoor is opened or an infection with a computer virus occurs before the intrusion detection unit 43x or the virus detection unit 44x detects the computer fraud, it is possible to protect the storage volume 64. This is because the storage volume 64 can not be accessed even when the host 40 tries to acquire data, and, on the other hand, a computer virus existing in the storage volume 64 can not be loaded onto the memory 45 and executed by the processor 46.

[Second Embodiment]

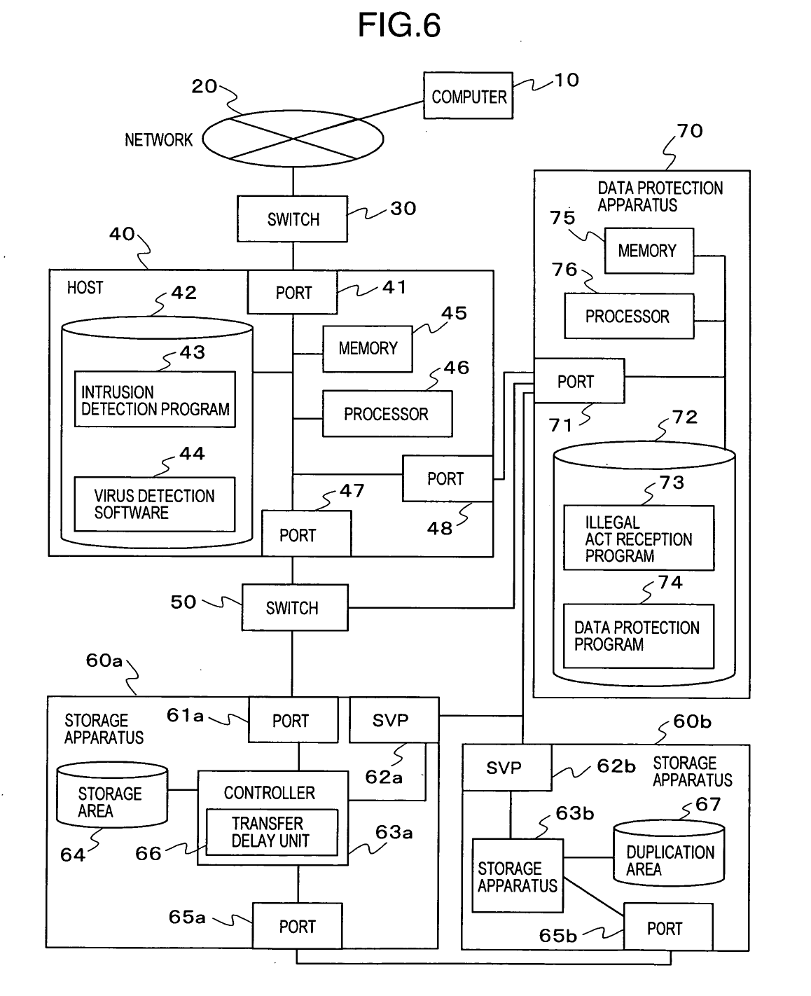

FIG. 6 is a block diagram showing a system configuration of a second embodiment of the present invention.

A system of the second embodiment comprises a front-end switch 30, a host 40, a back-end switch 50, storages 60a and 60b, and a data protection apparatus 70, and is connected to a network 20. Further, a computer 10 is connected to the network 20.

The computer 10, the network 20, the front-end switch 30, the host 40, and the back-end switch 50 may respectively have the same configuration and function as the first embodiment.

In comparison with the storage 60 of the first embodiment, the storage 60a further comprises a port 64a as an interface with the storage 60b, and a transfer delay unit 66 for delaying data reflection from the storage volume 64 onto a replicated volume 67 for a certain period of time.

In comparison with the storage 60 of the first embodiment, the storage 60b further comprises a port 65b as an interface with the storage 60a, and the replicated volume 67 for holding data duplicated from the storage volume 64.

Although, in the present embodiment, the transfer delay unit 66 is described as one implemented inside the controller 63a, the transfer delay unit 66 may be provided inside the controller 63b or may be provided as an independent apparatus between the port 65a and the port 65b. Further, although, in the present embodiment, each of the storages 60a and 60b is described as an independent apparatus, the storages 60a and 60b may be a single storage. In other words, the storage volume 64 and the replicated volume 67 may exist in the same single storage. Further, although only one replicated volume 67 is described in the present embodiment, a plurality of replicated volumes may exist. Further, each of the ports 65a and 65b is described as one port, however, there may exist a plurality of ports 65a and a plurality of ports 65b.

The configuration of the data protection apparatus 70 is similar to the first embodiment. However, a data protection unit 74x, which is virtually realized when a processor 76 executes a data protection program 74, further has a function of stopping data reflection from the storage volume 64 onto the replicated volume 67, in addition to the functions of the first embodiment.

Operation in the system of the present embodiment is fundamentally similar to that of the first embodiment. However, the present embodiment is different from the first embodiment in that the replicated volume 67 for holding data duplicated from the storage volume 64 is set in advance, and the transfer delay unit 66 is set so that data reflection from the storage volume 64 onto the replicated volume 67 is delayed by ΔT. As a result, in a regular operation, the replicated volume 67 always holds data of the storage volume 64 of ΔT time before.

Next, will be described a flow from occurrence of an computer fraud against the host 40 to protection of data in the storage volume 64 in the system of the present embodiment. Operation is similar to the first embodiment until the data protection unit 74x instructs the switch 50 or the SVP 62a to change the configuration so as to disconnect the back-end path between the host 40 and the storage volume 64. In addition to this operation, in the present embodiment, the data protection unit 74x instructs the controller 63a or the controller 63b through the port 71 and the SVP 62a or the SVP 62b to cancel or temporarily stop the replication relation (data reflection) between the storage volume 64 and the replicated volume 67.

As a result, in comparison with the first embodiment, the present embodiment can further secure data, which was held in the storage volume 64 ΔT time before an computer fraud against the host 40 is detected in the replicated volume 67.

Here, to attain an object of securing data held in the storage volume 64 ΔT time before an computer fraud against the host 40 is detected, it is sufficient to cancel or temporarily stop the replication relation (data reflection) between the storage volume 64 and the replicated volume 67. And, it is not necessary to disconnect the back-end path between the host 40 and the storage volume 64.

When it is assumed that the intrusion detection unit 43x and the virus detection unit 44x can detect an computer fraud in less than T1 at worst from the time of occurrence of the computer fraud, by setting ΔT time to satisfy ΔT≧T1, it is secured that the data is stored in the replicated volume 67 before the occurrence of an computer fraud. Accordingly, even if data held in the storage volume 64 is damaged, the system can be restored rapidly by using data stored in the replicated volume 67.

[Third Embodiment]

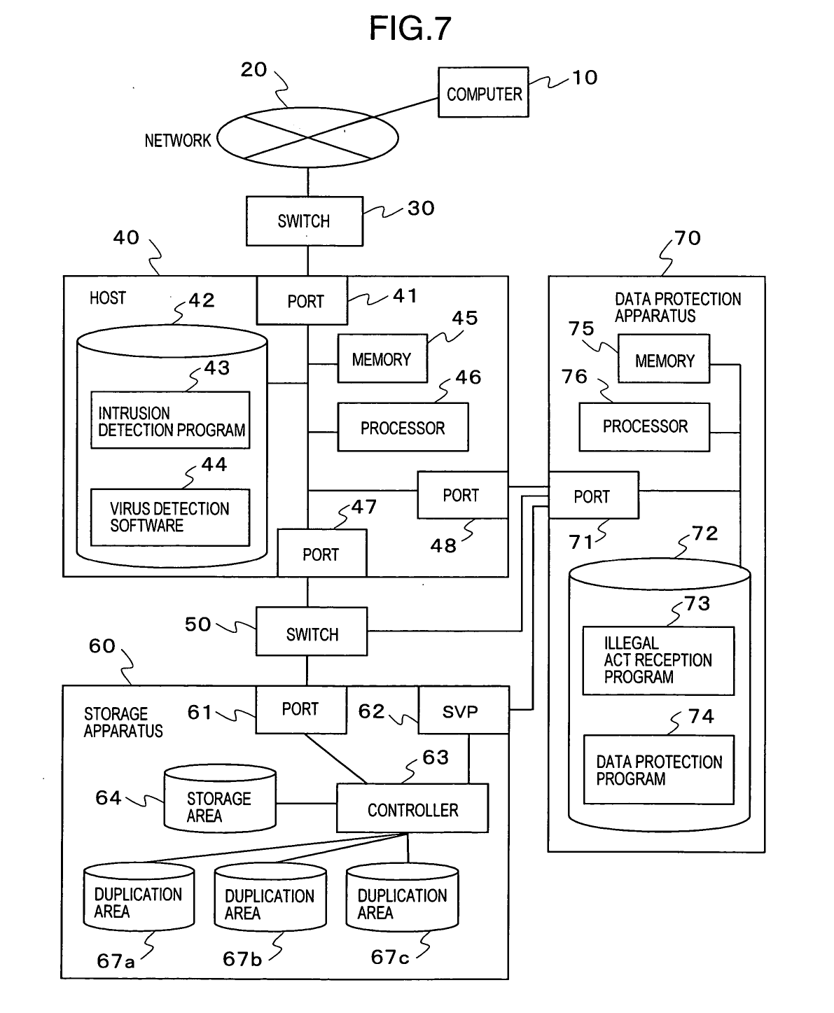

FIG. 7 is a block diagram showing a system configuration of a third embodiment.

A system of the third embodiment comprises a front-end switch 30, a host 40, a back-end switch 50, a storage 60, and a data protection apparatus 70, and is connected to a network 20. Further, a computer 10 is connected to the network 20.

The computer 10, the network 20, the front-end switch 30, the host 40, and the back-end switch 50 may each have the same configuration and function as the first embodiment.

In comparison with the first embodiment, the storage 60 further comprises replicated volumes 67a-67c, which are areas for storing data duplicated from the storage volume 64. Although, in the present embodiment, a plurality of storage volumes 67a-67c are provided in the same storage 60 as the storage volume 64, the storage volumes 67a-67c may be provided in another storage, as shown in the second embodiment. Further, although three replicated volumes exist in the present embodiment, any number of replicated volumes may exist as far as there exist a plurality of storage volumes.

A configuration of the data protection apparatus 70 is similar to the second embodiment. However, a data protection unit 74x, which is virtually realized when a processor 76 executes a data protection program 74, further has a function of switching among replicated volumes 67a-67c, onto which data of the storage volume 64 is reflected, sequentially and periodically at ΔT′ intervals, in addition to the functions of the second embodiment.

Operation in the system of the present embodiment is fundamentally same as the first embodiment. However, the present embodiment is different from the first embodiment in that the replicated volumes 67a-67c for holding data duplicated from the storage volume 64 are set in advance. Further, it is different that the data protection unit 74x instructs the controller 63 through the port 71 and the SVP 62 at ΔT′ intervals to switch the replicated volume onto which data of the storage volume 64 is reflected.

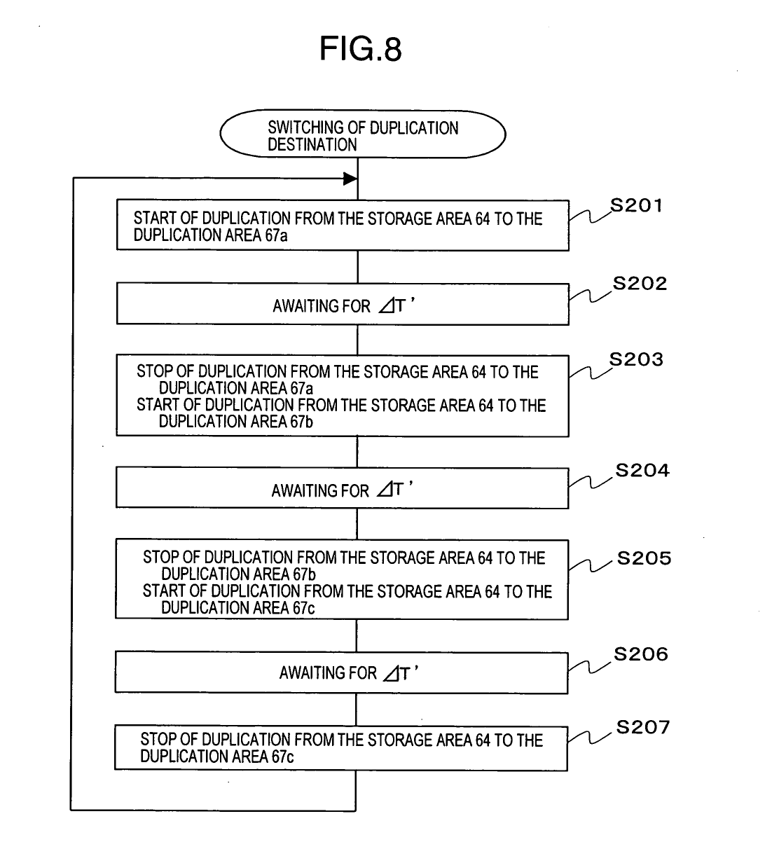

FIG. 8 is a sequence diagram showing a flow of switching among the replicated volumes 67a-67c onto which data of the storage volume 64 is reflected in the present embodiment.

The data protection unit 74x instructs the controller 63 through the port 71 and the SVP 62 to reflect data of the storage volume 64 onto the replicated volume 67a (S201). Next, after the period of ΔT′ (S202), the data protection unit 74x instructs the controller 63 through the port 71 and the SVP 62 to temporarily stop the replication relation between the storage volume 64 and the replicated volume 67a and to reflect data of the storage volume 64 onto the replicated volume 67b (S203). Further, after the period of ΔT′ (S204), the data protection unit 74x instructs the controller 63 through the port 71 and the SVP 62 to temporarily stop the replication relation between the storage volume 64 and the replicated volume 67b and to reflect data of the storage volume 64 onto the replicated volume 67c (S205).

Further, after the period of ΔT′ (S206), the data protection unit 74x instructs the controller 63 through the port 71 and the SVP 62 to temporarily stop the replication relation between the storage volume 64 and the replicated volume 67c (S207), and to reflect data of the storage volume 64 onto the replicated volume 67a (S201). Repeating these processes, the data protection unit 74x switches, at ΔT′ intervals, among replicated volumes 67a-67c, onto which data of storage volume 64 is reflected. Here, the controller 63 may perform the processing of switching, at ΔT′ intervals, the replicated volume onto which data of the storage volume 64 is reflected.

As described above, in a regular operation, the replicated volumes 67a-67c hold respective snapshots of the storage volume 64 with ΔT′ time differences.

Some storages can hold a number of replications of the storage volume 64 by limiting the number of replicated volumes onto which data of the storage volume can be directly reflected, and by reflecting data of the above-mentioned replicated volumes onto another plurality of replicated volumes respectively (cascade connection).

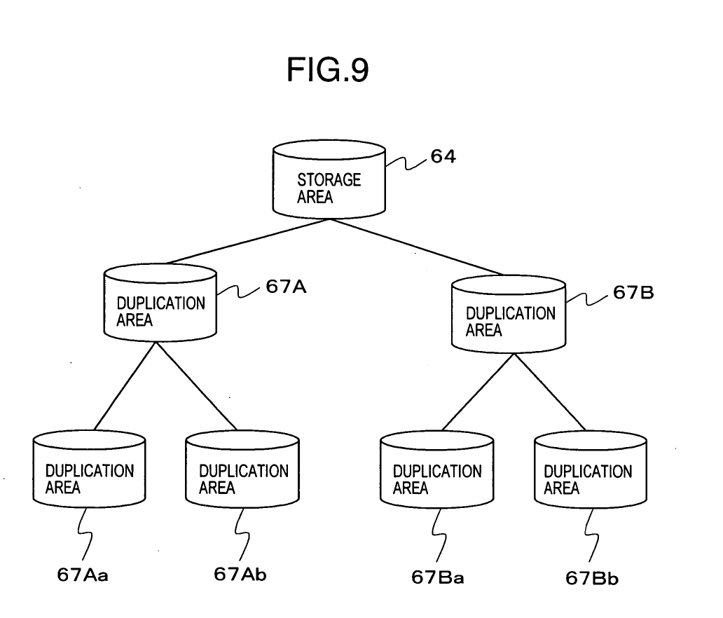

FIG. 9 is a diagram showing an example of a relation between a storage volume and replicated volumes in the case of cascade connection.

A replicated volume 67A is a replication destination of the storage volume 64 and, at the same time, a replication source of replicated volumes 67Aa and 67Ab. In the same way, a replicated volume 67B is a replication destination of the storage volume 64 and, at the same time, replication source of replicated volumes 67Ba and 67Bb.

With respect to a storage having the above-described configuration, the data protection unit 74x instructs the controller 63 through the port 71 and the SVP 62 to reflect data in the storage volume 64 onto the replicated volume 67A and to reflect data in the replicated volume 67A onto the replicated volume 67Aa. Next, after the period of ΔT′, the data protection unit 74x instructs the controller 63 through the port 71 and the SVP 62 to temporarily stop the replication relation between the replicated volume 67A and the replicated volume 67Aa, and to reflect data in the replicated volume 67A onto the replicated volume 67Ab. Further, after the period of ΔT′, the data protection unit 74x instructs the controller 63 through the port 71 and the SVP 62 to temporarily stop the replication relation between the replicated volume 67A and replicated volume 67Ab and the replication relation between the storage volume 64 and the replicated volume 67A, and to reflect data in the storage volume 64 onto the replicated volume 67B and data in the replicated volume 67B onto the replicated volume 67Bb. Further, after the period of ΔT′, the data protection unit 74x instructs the controller 63 through the port 71 and the SVP 62 to temporarily stop the replication relation between the replicated volume 67B and the replicated volume 67Ba, and to reflect data in the replicated volume 67B onto the replicated volume 67Bb. Repeating these processes, the data protection unit 74x can make the replicated volumes 67Aa, 67Ab, 67Ba and 67Bb, which are located on end nodes, but not replication sources of other replicated volumes, hold respective snapshots of the storage volume 64 at ΔT′ time intervals.

In the present embodiment, a flow from occurrence of an computer fraud against the host 40 to protection of data in the storage volume 64 is similar to the second embodiment. However, replication relations to all the replicated volumes 67 are stopped.

As described above, in comparison with the first embodiment, the present embodiment is effective in that further N-number replicated volumes can hold snapshots of the storage volume 64 at ΔT′ time intervals. In the example of FIG. 3, N is three.

Here, to attain the object of securing data existing before an occurrence of an computer fraud against the host 40, it is sufficient to cancel or temporarily stop replication relations (data reflection) of the storage volume with all the replicated volumes 67. And, it is not necessary to disconnect the back-end path between the host 40 and the storage volume 64.

Assuming that the intrusion detection unit 43x and the virus detection unit 44x can detect an computer fraud in less than T1 at worst from the time of the occurrence of the computer fraud, by setting ΔT′ to satisfy ΔT′ ≧T1/(N−2), it is assured that at least one replicated volume 67 holds data existing before the occurrence of an computer fraud. This is because, even in the worst case where an computer fraud is detected just after a replicated volume onto which data in the storage volume is reflected is switched, the N-number replicated volumes 67 respectively hold data in the storage volume 64 of zero time ago (the present replication destination), zero time ago (the replication destination just before the present one), ΔT′ time ago, . . . , and (N−2)ΔT′ time ago. In other words, if ΔT′ ≧T1/(N−2) is satisfied, the data of (N−2)ΔT′ time ago is older than the data of T1 time ago, which means the detected computer fraud occurred after the point of time of T1 time ago. Thus, at least one of the N-number replicated volumes 67 holds the data in the storage volume 64 of (N−2)ΔT′ time ago, which is the data that existed before the occurrence of the computer fraud. As a result, even if data in the storage volume 64 is damaged, the system can be restored rapidly by using data stored in one of the replicated volumes 67.

Further, analyzing a log file after detection of an computer fraud, it may be possible to definitely know the time when data in the storage volume 64 began to be destructed or the time when the computer fraud started. In the present embodiment, it is possible to secure the newest data before the mentioned time, namely, data as of T1/(N−2) time ago. In this regard, the present embodiment has an advantage over the second embodiment which generates data loss corresponding to the time period T1 at least.

Further, in the present embodiment, storing of log data in the storage volume 64 is useful also for detection of an computer fraud. Sometimes, crackers (intruders) alter the log data to delete traces of illegal access. In the present embodiment, the replicated volumes 67 can retain snapshots of log data at ΔT′ time intervals. For example, a log alteration detection program may be stored in the data protection apparatus 70, the host 40, another computer, the controller 63, or the like. When executed, the program virtually realizes a log alteration detection unit for detecting alteration of log data by comparing respective log data stored in the replicated volumes. Thus, it is possible to monitor an computer fraud against the host 40. Namely, when the log alteration detection unit detects an alteration of the log, and the log alteration detection unit notifies the computer fraud receiving program 73 of the alteration, data of the storage volume used by the host 40 can be protected. In addition, by analyzing snapshots of the log data stored in the replicated volumes, it becomes possible to specify a cracker trying to intrude again, or to take measures such as waylaying.

As described above, according to the present invention, it is possible to protect data of a computer system at the time of detecting an computer fraud against the computer system.

What is claimed is:

1. A data protection apparatus for protecting data in a storage volume in a computer system, with said computer system comprising said storage volume assigned for storing data, a computer for reading and writing data from and to said storage volume, and a storage control unit for controlling communication between said computer and said storage volume, wherein said data protection apparatus comprises:
an event detection unit for detecting an event occurrence; and
a path disconnection unit for instructing said storage control unit to stop communication between said computer and said storage volume, when said event detection unit detects an event.

2. A data protection apparatus according to claim 1, wherein:
said computer system further comprises an illegal intrusion detection unit for detecting an illegal intrusion against said computer;
said event detection unit receives a detection of the illegal intrusion from said illegal intrusion detection unit; and
when said event detection unit receives the detection of the illegal intrusion, said path disconnection unit instructs said storage control unit to stop communication between said computer and said storage volume.

3. A data protection apparatus according to claim 1, wherein:
said computer system further comprises a computer virus detection unit for detecting a computer virus in said storage volume;
said event detection unit receives a detection of the computer virus from said computer virus detection unit; and
when said event detection unit receives the detection of the computer virus, said path disconnection unit instructs said storage control unit to stop communication between said computer and said storage volume.

4. A data protection method for protecting data in a storage volume in a computer system, with said computer system comprising said storage volume assigned for storing data, a computer for reading and writing data from and to said storage volume and a storage control unit for controlling communication between said computer and said storage volume, wherein said data protection method comprises steps of:
detecting an event occurrence; and
instructing said storage control unit to stop communication between said computer and said storage volume, when said event is detected.

5. A program for making an information processing apparatus perform data protection of a storage volume in a computer system, with said computer system comprising said storage volume assigned for storing data, a computer for reading and writing data from and to said storage volume, and a storage control unit for controlling communication between said computer and said storage volume, wherein said program makes said information processing apparatus perform processes of:
detecting an event occurrence; and
instructing said storage control unit to stop communication between said computer and said storage volume, after said event is detected.

6. A computer system comprising a storage volume assigned for storing data, a computer for reading and writing data from and to said storage volume, a storage control unit for controlling communication between said computer and said storage volume, and a data protection apparatus for protecting data in said storage volume, wherein:
said data protection apparatus comprises:
an event detection unit for detecting an event occurrence; and
a path disconnection unit for instructing said storage control unit to stop communication between said computer and said storage volume, when said event detection unit detects an event.

7. A data protection apparatus for protecting data in a storage volume in a computer system, with said computer system comprising said storage volume assigned for storing data, a replicated volume assigned for storing data duplicated from said storage volume, and a storage control unit for controlling data transfer from said storage volume to said replicated volume, wherein said data protection apparatus comprises:
an event detection unit for detecting an event occurrence; and
a replication stopping unit for instructing said storage control unit to stop data transfer from said storage volume to said replicated volume, when said event detection unit detects an event.

8. A data protection apparatus according to claim 7, wherein:
said computer system further comprises a computer for reading and writing data from and to said storage volume an illegal intrusion detection unit for detecting an illegal intrusion into said computer;
said event detection unit receives a detection of the illegal intrusion from said illegal intrusion detection unit; and
when said event detection unit receives the detection of the illegal intrusion, said replication stopping unit instructs said storage control unit to stop data transfer from said storage volume to said replicated volume.

9. A data protection apparatus according to claim 7, wherein:
said computer system further comprises a computer virus detection unit for detecting a computer virus in said storage;
said event detection unit receives the detection of the computer virus from said computer virus detection unit; and
when said event detection unit receives the detection of the computer virus, said replication stopping unit instructs said storage control unit to stop data transfer from said storage volume to said replicated volume.

10. A data protection method for protecting data in a storage volume in a computer system, with said computer system comprising said storage volume assigned for storing data, a replicated volume assigned for storing data duplicated from said storage volume, and a storage control unit for controlling data transfer from said storage volume to said replicated volume, wherein said data protection method comprises steps of:
detecting an event occurrence; and
instructing said storage control unit to stop data transfer from said storage volume to said replicated volume, when said event is detected.

11. A program for making an information processing apparatus perform data protection of a storage volume in a computer system, with said computer system comprising said storage volume assigned for storing data, a replicated volume assigned for storing data duplicated from said storage volume, and a storage control unit for controlling data transfer from said storage volume to said replicated volume, wherein said program makes said information processing apparatus perform processes of:
detecting an event occurrence; and
instructing said storage control unit to stop data transfer from said storage volume to said replicated volume, when said event is detected.

12. A storage medium that stores the program according to claim 5 and can be read by the information processing apparatus.

13. A storage medium that stores the program according to claim 11 and can be read by the information processing apparatus.

14. A computer system comprising a storage volume assigned for storing data, a replicated volume assigned for storing data duplicated from said storage volume, a storage control unit for controlling data transfer from said storage volume to said replicated volume, and a data protection apparatus for protecting data in said storage volume, wherein:
said data protection apparatus comprises:
an event detection unit for detecting an event occurrence; and
a replication stopping unit for instructing said storage control unit to stop data transfer from said storage volume to said replicated volume, when said event detection unit detects an event.

15. A computer system according to claim 14, wherein:
write data to said storage volume is transferred by said storage control unit to said replicated volume with a delay of a given time.

16. A computer system according to claim 14, wherein:
as said replicated volume, a plurality of replicated volumes are provided; and
said storage control unit switches a transfer destination of write data of said storage volume, at given time intervals among said plurality of replicated volumes.

17. A computer system according to claim 16, wherein:
data transferred to said plurality of replicated volumes is further transferred to another plurality of replicated volumes.

18. A computer system according to claim 16, wherein:
said computer system further comprises an alteration detection unit that reads given data in said plurality of replicated volumes to detect respective differences between the given data; and
the event detected by said event detection unit is a detection result of the differences between the given data, with said detection result being received from said alteration detection unit.

19. A computer system according to claim 18, wherein:
said computer system further comprises a computer for reading and writing data from and to said storage volume;
said storage control unit further controls communication between said computer and said storage volume; and
said data protection apparatus instructs said storage controller to stop communication between said computer and said storage when said event detection unit detects said event.

20. A computer system comprising:
a storage apparatus comprising a storage volume assigned for storing data, a replicated volume assigned for storing data duplicated from said storage volume, a host computer for reading and writing data from and to said storage volume, a storage control unit for controlling communication between said host computer and said storage volume, and a data protection apparatus for protecting data in said storage volume, wherein:
said host computer detects an illegal intrusion and sends a notification of the detected illegal intrusion to said data protection apparatus;
said data protection apparatus receives said notification and gives said storage control unit an instruction to stop communication between said computer and said storage volume; and
said storage control unit, receiving said instruction, rejects access from outside to the storage volume of said storage apparatus.
